(19) United States
(12) Patent Application Publication
(10) Pub. No.: US 2008/0153231 A1
(43) Pub. Date: Jun. 26, 2008

(54) MANUFACTURING METHOD OF NON-VOLATILE MEMORY

(75) Inventors: Saysamone Pittikoun, Taipei City (TW); Houng-Chi Wei, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: POWERCHIP SEMICONDUCTOR CORP., Hsinchu (TW)

(21) Appl. No.: 12/036,299

(22) Filed: Feb. 25, 2008

Related U.S. Application Data
(62) Division of application No. 11/162,329, filed on Sep. 7, 2005.

(30) Foreign Application Priority Data
Mar. 4, 2005 (TW) 94106551

(51) Int. Cl. H01L 21/336

(52) U.S. Cl. 438/261; 257/E21.409

(57) ABSTRACT

A non-volatile memory having a plurality of memory units is provided. Each memory unit includes a first memory cell and a second memory cell. The first memory cell is disposed on the substrate. The second memory cell is disposed on one sidewall of the first memory cell and the substrate. The first memory cell includes a first control gate disposed on the substrate and a composite layer disposed between the first control gate and the substrate. The second memory cell includes a pair of floating gates disposed on the substrate, a second control gate disposed on the upper surface of the two floating gates, an inter-gate dielectric layer disposed between the floating gate and the second control gate, a tunneling dielectric layer disposed between the floating gate and the substrate and a gate dielectric layer disposed between the bottom of the second control gate and the substrate.

### CROSS-REFERENCE TO RELATED APPLICATION

This application is a divisional of an application Ser. No. 11/162,329, filed on Sep. 7, 2005, now pending, which claims the priority benefit of Taiwan application serial no. 94106551, filed on Mar. 4, 2005. The entirety of each of the above-mentioned patent applications is hereby incorporated by reference herein and made a part of this specification.

### BACKGROUND OF THE INVENTION

1. Field of the Invention

The present invention relates to a memory device. More particularly, the present invention relates to a non-volatile memory and manufacturing method and operating method thereof.

2. Description of the Related Art

Among various types of non-volatile memory products, electrically erasable programmable read only memory (EEPROM) is one widely used in personal computer systems and electronic equipment, as data can be stored, read out or erased from the EEPROM many times and stored data are retained even after power is cut off.

Typically, the floating gates and the control gates of the EEPROM non-volatile memory are fabricated using doped polysilicon. Furthermore, the floating gate and the control gate are isolated from each other by an inter-gate dielectric layer and the floating gate and the substrate are isolated through a tunneling dielectric layer. To write data into or erase data from the memory, a biased voltage is applied to the control gate and the source/drain region so that electric charges are injected into the floating gate or pulled out from the floating gate. To read data from the memory, an operating voltage is applied to the control gate. Because the threshold voltage of the floating gate has been changed through a previous write/erase operation, the difference in the threshold voltage is interpreted as a data value of ‘0’ or ‘1’ in the data read-out.

However, because the floating gate is a layer of joining semiconductor material (a polysilicon layer), the injected electric charges will distribute evenly within the entire floating gate. Therefore, in this type of memory, only a single bit of data is allowed to be stored in each memory cell and thus cannot be used as a multi-level memory cell device.

Furthermore, to prevent the data judgment errors due to serious over-erasing, an additional select gate is often disposed on the sidewalls of the control gate and the floating gate above the substrate to form a split-gate structure.

Yet, a device having a split-gate structure requires a large surface area for accommodating the select gate. Hence, it is difficult to increase the level of integration of the non-volatile memory.

### SUMMARY OF THE INVENTION

Accordingly, at least one objective of the present invention is to provide a non-volatile memory and manufacturing method and operating method thereof that can increase the level of integration of memory cells and improve device performance.

At least a second objective of the present invention is to provide a non-volatile memory and manufacturing method and operating method thereof that utilizes source-side injection (SSI) to carry out programming operations. Hence, the speed for programming the memory is increased and the performance of the memory is improved.

At least a third objective of the present invention is to provide a non-volatile memory and manufacturing method and operating method thereof that can increase the storage capacity of the memory, simplify the process and reduce the production cost.

To achieve these and other advantages and in accordance with the purpose of the invention, as embodied and broadly described herein, the invention provides a non-volatile memory unit. The non-volatile memory unit includes a first memory cell, a first insulating layer and a second memory cell. The first memory cell is disposed on the substrate. The second memory cell is disposed on the substrate and is adjacent to the first memory cell through the first insulating layer. The first memory cell further includes a first control gate disposed on the substrate and a first composite layer disposed between the first control gate and the substrate. Furthermore, the first composite layer includes a first dielectric layer, a first charge-trapping layer and a second dielectric layer sequentially formed over the substrate. The second memory cell includes a pair of floating gates disposed on the substrate such that one of the floating gates connects with the first memory cell through the first insulating layer, a second control gate disposed on the upper surface of the floating gates with the bottom of the second control gate located on the substrate between the two floating gates, an inter-gate dielectric layer disposed between the floating gate and the second control gate, a tunneling dielectric layer disposed between the floating gate and the substrate and a first gate dielectric layer disposed between the bottom of the second control gate and the substrate. The floating gates are doped polysilicon spacers formed in a self-aligned anisotropic etching operation, for example. Moreover, the arc-shaped sidewall of the respective floating gates faces each other.

The present invention also provides an alternative non-volatile memory. The non-volatile memory includes a plurality of the aforementioned non-volatile memory units, a select unit, a first doped region and a second doped region. The non-volatile memory units are serially connected with each other through a second insulating layer. The select unit is disposed on the substrate and connected to the outermost second memory cell through a third insulating layer. The select unit includes a select gate disposed on the substrate, a second composite layer disposed between the select gate and the substrate. Furthermore, the second composite layer includes a third dielectric layer, a second charge-trapping layer and a fourth dielectric layer sequentially formed over the substrate. The first doped region is disposed in the substrate on the outer side of the outermost first memory cell. The second doped region is disposed in the substrate on the outer side of the select unit.

In the non-volatile memory of the present invention, the first memory cells and the second memory cells are alternately arranged to form memory columns. Because there is no gap between each first memory cell and an adjacent second memory cell and there is no gap between the select unit and an adjacent second memory cell, the overall level of integration of the memory cell array is increased. Furthermore, each second memory cell includes two separated floating gates so that each memory cell can store two bits of data. In addition, the first memory cell can store a single bit of data. Therefore, each memory unit can store three bits of data. Consequently, the storage capacity is increased and each memory cell may serve as a multi-level memory device.

The present invention also provides another non-volatile memory. The non-volatile memory includes a substrate, a plurality of stacked gate structures, a plurality of conductive spacers, an insulating layer, a tunneling dielectric layer, a plurality of second gates, a gate dielectric layer, an inter-gate dielectric layer, a first doped region and a second doped region. The stacked gate structures are disposed on the substrate. Each stacked gate structure includes a composite layer and a first gate sequentially stacked on the substrate. The composite layer has at least a charge-trapping layer and every pair of stacked gate structures has a gap. The conductive spacers are disposed on the sidewalls of the stacked gate structures. The insulating layer is disposed between the conductive spacers and the stacked gate structures. The tunneling dielectric layer is disposed between the conductive spacers and the substrate. The second gate completely fills the gap between two adjacent stacked gate structures and covers the upper surface of the conductive spacers. The second gates, together with the stacked gate structures, form a memory cell column. The gate dielectric layer is disposed between the second gates and the substrate. The inter-gate dielectric layer is disposed between the second gates and the conductive spacers. The first doped region and the second doped regions are disposed in the substrate on the respective sides of the memory cell column.

The non-volatile memory of the present invention includes two separated conductive spacers that may serve as floating gates for storing two bits of data. Moreover, the charge-trapping layer within each stacked gate structure can store a single bit of data. Hence, a memory unit that includes a second gate and a stacked gate structure can store up to three bits of data. Consequently, the storage capacity is increased and each memory cell may serve as a multi-level memory device.

The present invention also provides a method of operating a non-volatile memory, adapted for a memory unit array. The memory unit array includes a plurality of memory units each having a first memory cell and a second memory cell. The memory cell units are serially connected without any gaps to form a memory column. The first memory cell has at least a charge-trapping layer. Each second memory cell has at least a pair of separated floating gates. A plurality of select units is disposed to connect with the outermost second memory cell of the respective memory columns. A plurality of source regions are disposed in the substrate on the outer side of the outermost first memory cell of the respective memory columns. A plurality of drain regions is disposed in the substrate on the outer side of the select units of the respective memory columns. A plurality of first word lines are aligned in parallel in the row direction to connect with the control gate of the first memory cells in the same row. A plurality of second word lines are aligned in parallel in the row direction to connect with the control gate of the second memory cells in the same row. A plurality of select gate lines connects with the gate of the select units in the same column. A plurality of bit lines is aligned in parallel in the column direction to connect with the drain regions in the same column. A plurality of source lines is disposed to connect with the source regions in the same column. To perform a first programming operation, 0V is applied to the selected bit line, a first voltage is applied to the selected first word line adjacent to the second word line coupled with the selected second memory cell and close to the drain region, a second voltage is applied to the non-selected first word lines, second word lines and select gate lines, and a third voltage is applied to the selected source line. Hence, source-side injection (SSI) is triggered to program the selected second memory cell so that a first bit of data is stored in the floating gate close to the drain region of the selected second memory cell. To perform a second programming operation, 0V is applied to the selected bit line, the first voltage is applied to the second word line that couples with the selected second memory cell, the second voltage is applied to the non-selected first word lines, second word lines and select gate lines, and the third voltage is applied to the selected source line. Hence, source-side injection (SSI) is triggered to program the selected second memory cell so that a second bit of data is saved in the floating gate close to the source region of the selected second memory cell. To perform a third programming operation, 0V is applied to the selected bit line, the third voltage is applied to the selected source line and the selected second word line adjacent to the first word line that couples with the selected first memory cell and close to the drain, and the second voltage is applied to the non-selected first word lines, second word lines and select gate lines. Hence, source-side injection (SSI) is triggered to program the selected first memory cell so that a third bit of data is saved in the charge-trapping layer of the selected first memory cell.

To perform an erasing operation of the aforementioned non-volatile memory, the selected bit line and the source line are set in a floating state, a fourth voltage is applied to the selected select gate line and the substrate, and 0V is applied to the other non-selected first word lines and second word lines. Hence, F-N tunneling is triggered to erase the data.

To perform a first reading operation of the aforementioned non-volatile memory, 0V is applied to the selected bit line, a fifth voltage is applied to the source line and the second word line that couple with the selected second memory cell, and a sixth voltage is applied to the other non-selected first word lines, second word lines and select gate lines. Hence, a first bit of data is read from the floating gate close to the drain region of the selected second memory cell. To perform a second reading operation, 0V is applied to the selected source line, the fifth voltage is applied to the bit line and the second word line that couple with the selected second memory cell, and the sixth voltage is applied to the other non-selected first word lines, second word lines and select gate lines. Hence, a second bit of data is read from the floating gate close to the source region of the selected second memory cell. To perform a third reading operation, 0V is applied to the selected bit line, the fifth voltage is applied to the source line and the first word line that couple with the selected first memory cell, and the sixth voltage is applied to the other non-selected first word lines, second word lines and select gate lines. Hence, a third bit of data is read from the charge-trapping layer of the selected first memory cell.

The method of operating the non-volatile memory according to the present invention utilizes the source-side injection effect for programming data into the memory cells and F-N tunneling effect to erase data from the memory cells. Furthermore, a bi-directional reading operation is used to read the left and the right data bit in the same selected memory cell. Because the electron injection efficiency is higher in the present invention, the memory cell current can be reduced and the operating speed can be increased. As a result, current consumption is minimized and power loss from the entire chip is reduced.

The present invention also provides a method of fabricating a non-volatile memory including the following steps. First, a substrate is provided and then a plurality of stacked gate structures is formed on the substrate. Each stacked gate structure includes a composite layer, a first gate and a cap layer sequentially formed on the substrate. The composite layer has at least a charge-trapping layer and there is a gap between every pair of stacked gate structures. Thereafter, an insulating layer is formed on the sidewalls of the stacked gate structures within the gap. A tunneling dielectric layer is formed over the substrate. After that, conductive spacers are formed over the insulating layer on the sidewalls of the stacked gate structures. Then, an inter-gate dielectric layer is formed on the substrate to cover at least the conductive spacers. A first conductive layer is formed over the substrate. The first conductive layer at least completely fills the gap between two adjacent stacked gate structures. After that, a portion of the first conductive layer is removed until the cap layer is exposed to form a plurality of second gates in the respective gaps between two adjacent stacked gate structures. The second gates, together with the stacked gate structure, form a memory cell column. Thereafter, a source region and a drain region are formed in the substrate on the respective sides of the memory cell column.

In the method of fabricating the non-volatile memory according to the present invention, the conductive spacers (floating gates) and the second gates (the control gates) are formed in the space between neighboring stacked gate structures to produce memory cells without performing photolithographic and etching processes. Hence, the process of fabricating non-volatile memory is simplified and overall production cost is reduced.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a top view of a non-volatile memory according to the present invention.

FIG. 1B is a schematic cross-sectional view along line A-A′ of FIG. 1A.

FIG. 1C is a schematic cross-sectional view of the structures of a memory cell and a select unit according to the present invention.

FIG. 2A is a schematic cross-sectional view of the programming data into a non-volatile memory according to one embodiment of the present invention.

FIG. 2B is a schematic cross-sectional view of programming data into a non-volatile memory according to another embodiment of the present invention.

FIG. 2C is a schematic cross-sectional view of programming data into a non-volatile memory according to yet another embodiment of the present invention.

FIG. 3 is a schematic cross-sectional view of erasing data from a non-volatile memory according to one embodiment of the present invention.

FIG. 4A is a schematic cross-sectional view of reading data from a non-volatile memory according to one embodiment of the present invention.

FIG. 4B is a schematic cross-sectional view of reading data from a non-volatile memory according to another embodiment of the present invention.

FIG. 4C is a schematic cross-sectional view of reading data from a non-volatile memory according to yet another embodiment of the present invention.

FIGS. 5A through 5D are schematic cross-sectional views showing the steps for fabricating a non-volatile memory according to the present invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

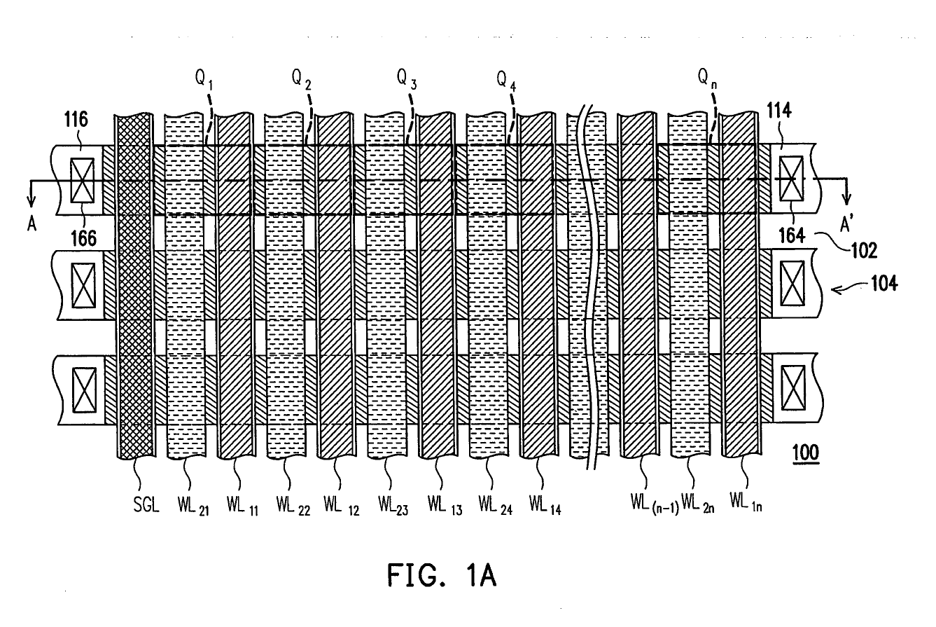

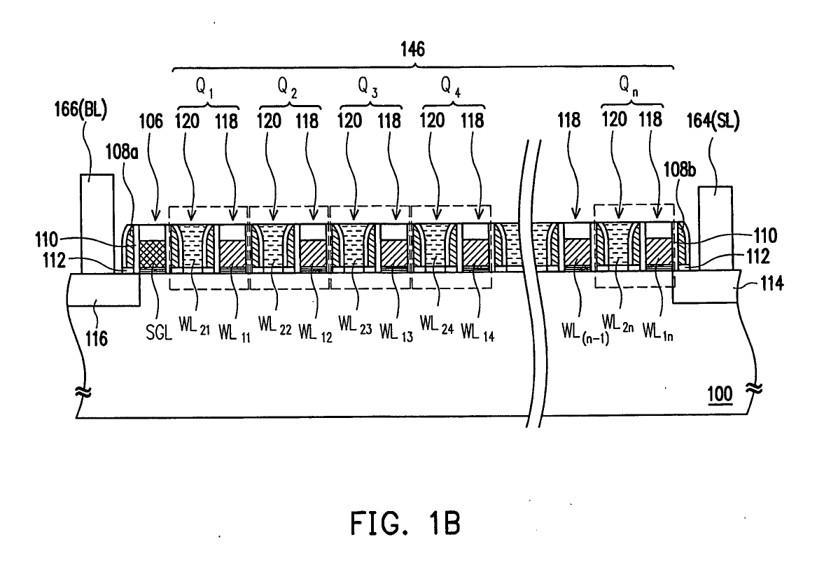

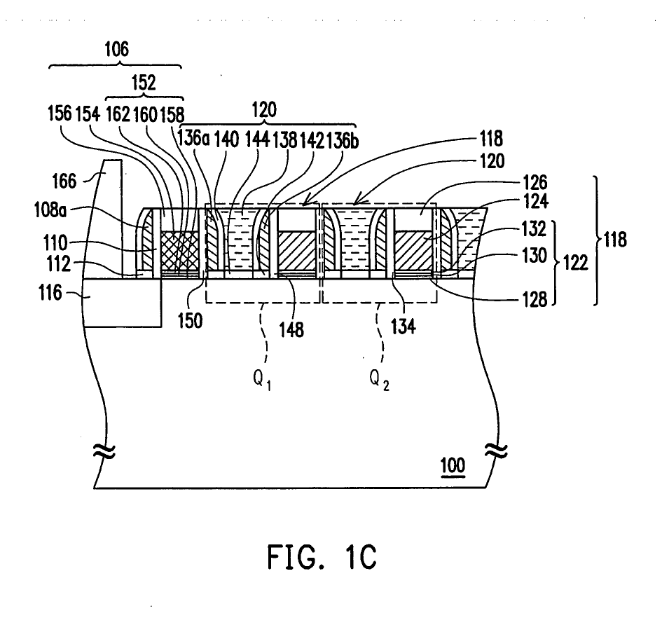

FIG. 1A is a top view showing a non-volatile memory according to the present invention. FIG. 1B is a schematic cross-sectional view along line A-A′ of FIG. 1A. FIG. 1C is a schematic cross-sectional view of the structures of a memory cell and a select unit according to the present invention. As shown in FIGS. 1A, 1B and 1C, the non-volatile memory of the present invention at least includes a substrate 100, a device isolation structure 102, an active region 104, a plurality of memory units Q1˜Qn, a select unit 106, a plurality of conductive spacers 108a, 108b, an insulating layer 110, a gate dielectric layer 112, a source region 114 and a drain region 116.

The substrate 100 is a silicon substrate, for example. The substrate 100 can be a P-type substrate or an N-type substrate. The device isolation structure 102 is disposed in the substrate 100 for defining the active region 104.

The memory units Q1˜Qn are disposed on the substrate 100. Each of the memory units Q1˜Qn includes a pair of memory cells 118 and 120.

The memory cells 118 are disposed on the substrate 100. Each memory cell 118 includes a composite layer 122, a control gate 124 and a cap layer 126, for example. The composite layer 122 includes a dielectric layer 128, a charge-trapping layer 130 and a dielectric layer 132 sequentially formed over the substrate 100. The control gate 124 is disposed on the substrate 100 and the composite layer 122 is disposed between the control gate 124 and the substrate 100. Furthermore, the dielectric layer 128 may serve as a tunneling layer for electric charges and the dielectric layer 132 may serve as a charge-stopping layer. The cap layer 126 is disposed on the control gate 124. The dielectric layer 128 is a silicon oxide layer, the charge-trapping layer 130 is a silicon nitride layer or a doped polysilicon layer and the dielectric layer 132 is a silicon oxide layer or an oxide/nitride/oxide stack material, for example. The control gate 124 is a doped polysilicon layer and the cap layer 126 is a silicon oxide layer, for example.

The memory cells 120 are disposed on the substrate 100 adjacent to the respective memory cells 118 through insulating layers 134. Each memory cell 120 includes a pair of floating gates 136a, 136b, a control gate 138, an inter-gate dielectric layer 140, a tunneling dielectric layer 142 and a gate dielectric layer 144, for example. The floating gates 136a and 136b are disposed on the substrate 100. The floating gate 136b connects with the memory cell 118 through the insulating layer 134. In the present embodiment, the floating gates 136a and 136b can be spacers formed in a self-aligned anisotropic etching operation such that the arc-shaped sidewall of the floating gates 136a and 136b face each other. The control gate 138 is disposed over the upper surface of the floating gates 136a and 136b. Furthermore, the bottom of the control gate 138 is disposed over the substrate 100 between the floating gates 136a and 136b. The inter-gate dielectric layer 140 is disposed between the floating gate 136a and the control gate 138 and between the floating gate 136b and the control gate 138. The tunneling dielectric layer 142 is disposed between the floating gate 136a and the substrate 100 and between the floating gate 136b and the substrate 100. The gate dielectric layer 144 is disposed between the bottom of the control gate 138 and the substrate 100. The floating gates 136a, 136b and the control gate 138 are doped polysilicon layers, for example. The inter-gate dielectric layer 140 is a silicon oxide layer or an oxide/nitride/oxide stack material, for example. The tunneling dielectric layer 142 and the gate dielectric layer 144 are silicon oxide layers, for example.

The memory units Q1˜Qn are serially connected in the active region 104 to form a memory column 146. Furthermore, the memory cells 118 and the memory cells 120 are alternately aligned so that no gap exists between them. The memory units Q1˜Qn within the memory column 146 are isolated from each other through an insulating layer 148. The memory columns 146 are isolated from each other through the device isolation structure 102.

The select unit 106 is disposed on the substrate 100 and is connected to the outermost memory cell 120 of the memory column 146 through an insulating layer 150. The select unit 106 includes a composite layer 152, a select gate 154 and a cap layer 156, for example. The composite layer 152 includes a dielectric layer 158, a charge-trapping layer 160 and a dielectric layer 162 sequentially formed over the substrate 100. The select gate 154 is disposed on the substrate 100. The composite layer 152 is disposed between the select gate 154 and the substrate 100. The cap layer 156 is disposed on the select gate 154. The dielectric layer 158 is a silicon oxide layer, the charge-trapping layer 160 is a silicon nitride layer or a doped polysilicon layer and the dielectric layer 162 is a silicon oxide layer or an oxide/nitride/oxide stack material, for example. The select gate 154 is a doped polysilicon layer and the cap layer 156 is a silicon oxide layer, for example.

Conductive spacers 108a and 108b are disposed on the outer sidewall of the select unit 106 and on the outer sidewall of the outermost memory cell 118. The conductive spacers 108a and 108b are doped polysilicon layers, for example. The insulating layer 110 is disposed between the conductive spacer 108a and the select unit 106 and between the conductive layer 108b and the outer sidewall of the outermost memory cell 118. The insulating layer 110 is a silicon oxide or a silicon nitride layer, for example. The gate dielectric layer 112 is disposed between the conductive spacer 108a and the substrate 100 and between the conductive spacer 108b and the substrate 100. The gate dielectric layer 112 is a silicon oxide layer, for example.

The source region 114 is disposed in the substrate 100 on the outer side of the outermost memory cell 118. The drain region 116 is disposed in the substrate 100 on the outer side of the select unit 106.

The source region 114 of each memory column 146 is electrically connected to a source line (SL) 164. Similarly, the drain region 116 of each memory column 146 is electrically connected to a bit line (BL) 166. The control gate 124 of the memory cells 118 in the same row are electrically connected to the respective first word lines WL11˜WL1n. The first word lines WL11˜WL1n are aligned in parallel in the row direction. The control gate 138 of the memory cells 120 in the same row are electrically connected to the respective second word lines WL21˜WL2n. The second word lines WL21˜WL2n are aligned in parallel in the row direction. The select gate 154 of the select units 106 in the same row are electrically connected to a select gate line SGL. The select gate line SGL is aligned in the row direction.

In the non-volatile memory in the present invention, the memory cells 118 and the memory cells 120 are alternately arranged to form a plurality of memory columns 146. Since there is no gap between the memory cell 118 and the memory cell 120 and there is no gap between the select unit 106 and the memory cell 120, the level of integration in the memory cell array can be increased. Furthermore, each memory cell 120 includes two separated floating gates 136a and 136b and hence two bits of data can be stored in a single memory cell. In addition, the memory cell 118 can store one bit of data. Consequently, each one of the memory units Q1˜Qn can store up to three bits of data so that the storage capacity of the non-volatile memory is increased and each memory cell can serve as a multi-level memory device.

In addition, the number of serially connected memory units in the present invention can be increased or decreased to meet the actual requirement. For example, 32 to 64 memory units can be serially connected together to form a memory column 146.

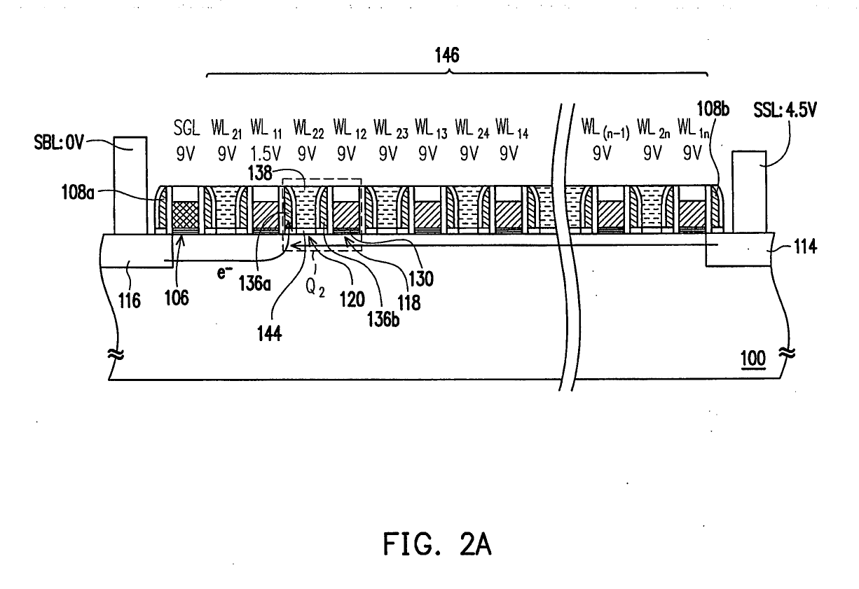

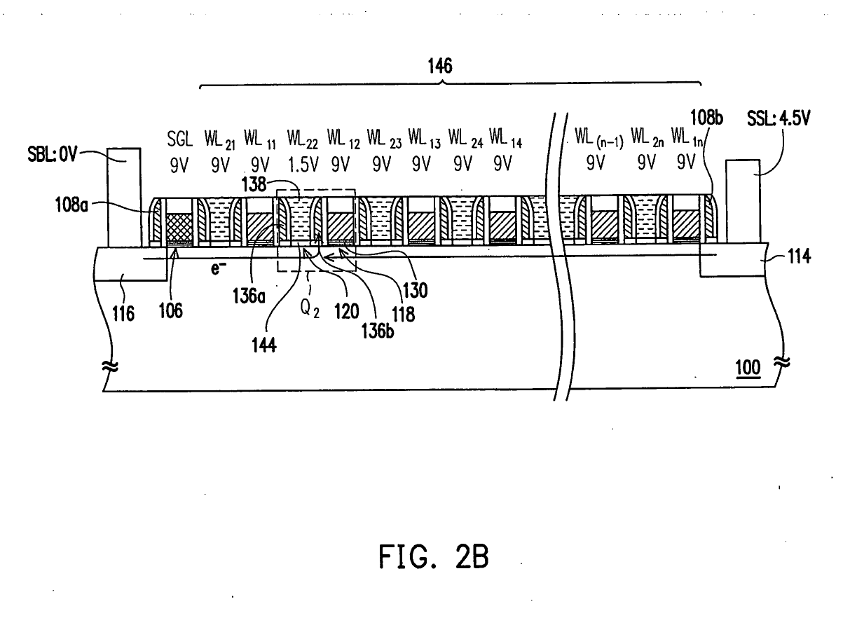

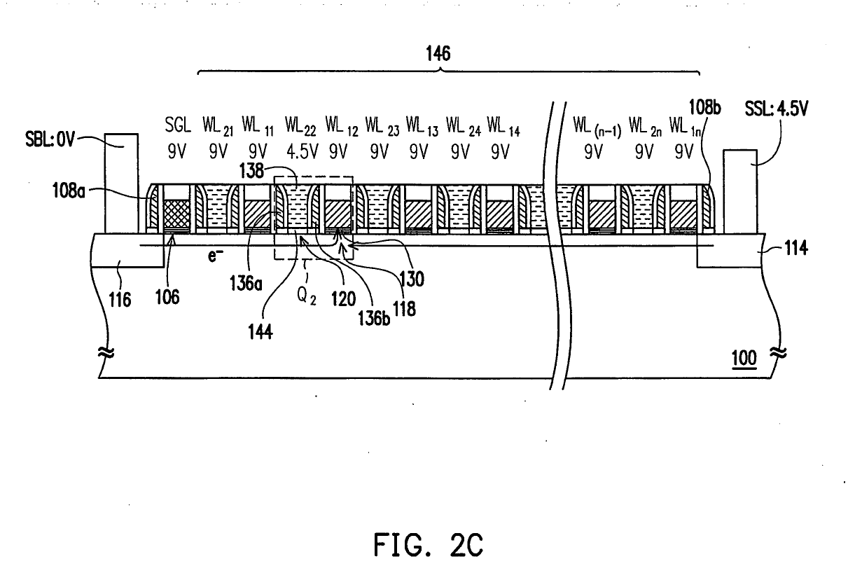

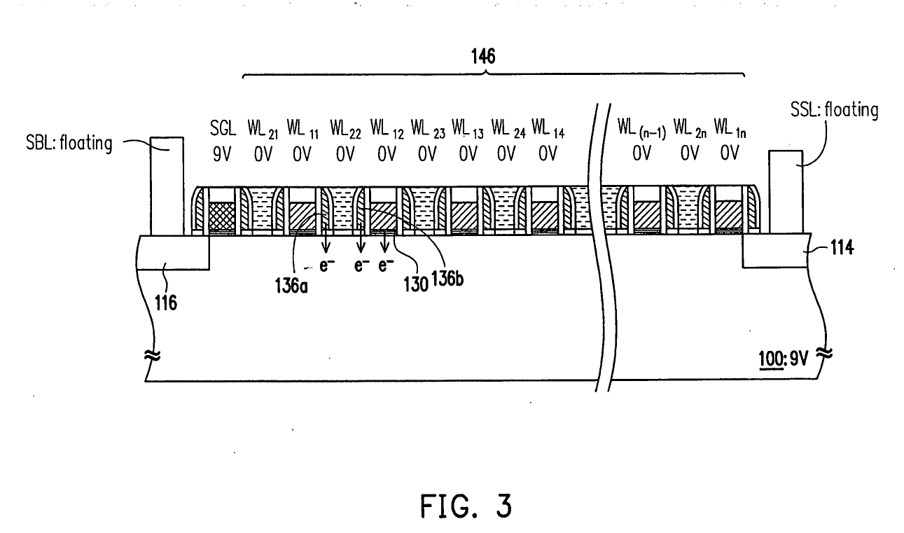

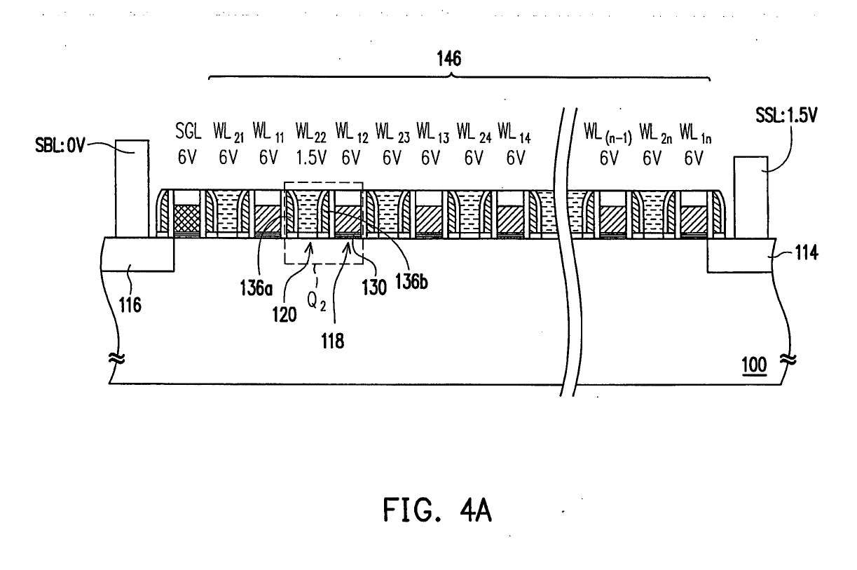

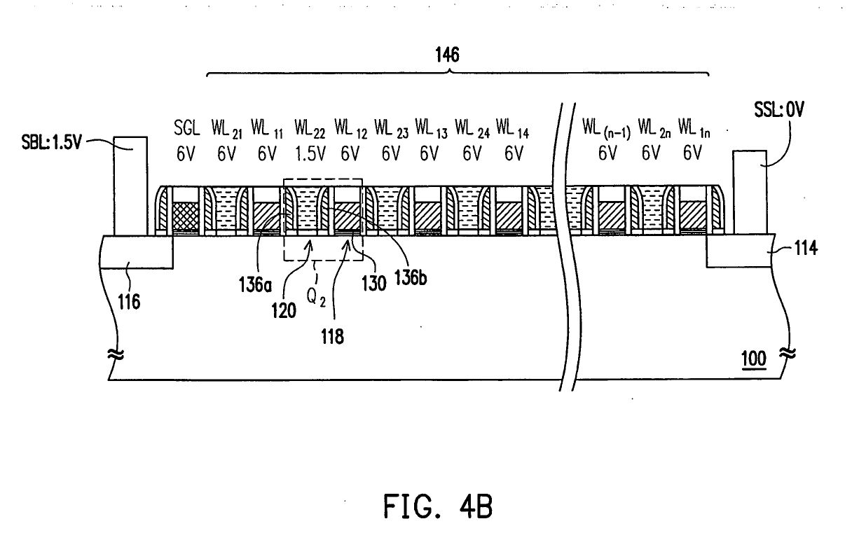

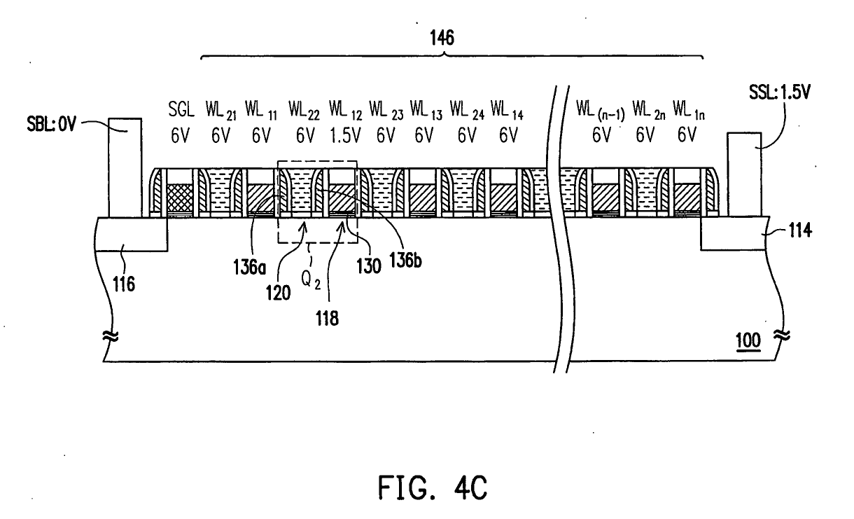

In the following, a method of operating the aforementioned non-volatile memory is described. FIG. 2A is a schematic cross-sectional view of programming data into a non-volatile memory according to one embodiment of the present invention. FIG. 2B is a schematic cross-sectional view of programming data into a non-volatile memory according to another embodiment of the present invention. FIG. 2C is a schematic cross-sectional view of programming data into a non-volatile memory according to yet another embodiment of the present invention. FIG. 3 is a schematic cross-sectional view of erasing data from a non-volatile memory according to one embodiment of the present invention. FIG. 4A is a schematic cross-sectional view of reading data from a non-volatile memory according to one embodiment of the present invention. FIG. 4B is a schematic cross-sectional view of reading data from a non-volatile memory according to another embodiment of the present invention. FIG. 4C is a schematic cross-sectional view of reading data from a non-volatile memory according to yet another embodiment of the present invention.

To perform a first programming operation, such as programming a first bit of data into the memory cell 120 of the memory unit Q2 as shown in FIG. 2A, 0V is applied to the selected bit line SBL, a first voltage such as 1.5V is applied to the selected first word line WL11 adjacent to the second word line WL22 that couples to the selected memory cell 120 and close to the drain region 116, a second voltage such as 9V is applied to the other non-selected first word lines WL12˜WL1n, second word lines WL21˜WL2n and the selected gate line SGL, and a third voltage such as 4.5V is applied to the selected source line SSL so that source-side injection (SSI) is triggered to program data into the selected memory cell, for example, the memory cell 120 of the memory unit Q2. Hence, a first bit of data is saved in the floating gate 136a close to the drain region 116 of the selected memory cell. In particular, the voltage applied to the second word line WL22 of the selected memory cell will couple with the floating gate 136a and generate a coupling voltage on the floating gate 136a. The coupling voltage is about 50%˜60% of the voltage applied to the second word line WL22, which is about 5V, for example.

To perform a second programming operation as shown in FIG. 2B, 0V is applied to the selected bit line SBL, a first voltage such as 1.5V is applied to the second word line WL22 that couples with the selected memory cell 120, a second voltage such as 9V is applied to the other non-selected first word lines WL11˜WL1n, second word lines WL21, WL23˜WL2n and the select gate line SGL, and a third voltage such as 4.5V is applied to the selected source line SSL so that source-side injection (SSI) is triggered to program data into the selected memory cell, for example, the memory cell 120 of the memory unit Q2. Hence, a second bit of data is saved in the floating gate 136b close to the source region 114 of the selected memory cell. In particular, the voltage applied to the first word lines WL11 and WL12 of the selected memory cell will couple with the floating gate 136a and the floating gate 136b respectively and generate a coupling voltage in the floating gate 136a and the floating gate 136b. The coupling voltage is about 50%˜60% of the voltage applied to the first word lines WL11 and WL12, which is about 4˜5V, for example.

To perform a third programming operation as shown in FIG. 2C, 0V is applied to the selected bit line SBL, a third voltage such as 4.5V is applied to the second word line WL22 adjacent to the first word line WL12 that couples with the selected memory cell 118 and close to the drain 116, and the source line SSL, a second voltage such as 9V is applied to the other non-selected first word lines WL11˜WL1n, second word lines WL21, WL23˜WL2n and the select gate line SGL so that source-side injection (SSI) is triggered to program data into the selected memory cell, for example, the memory cell 118 of the memory unit Q2. Hence, a third bit of data is saved in the charge-trapping layer 130 of the selected memory cell. In particular, the voltage applied to the selected second word line WL22 adjacent to the first word line WL12 that couples with the selected memory cell 118 and close to the drain region 116 will open the channels underneath the second word line WL22 and the floating gates 136a, 136b. Thus, electric charges can be stored inside the charge-trapping layer 130.

In the operating method of the present invention, when data need to be stored in a selected memory cell, for example, memory cell 120 in the memory unit Q2, in its floating gate 136a close to the drain region 116, the other memory cell 118 adjacent to the selected memory cell 120 and close to the drain region 116 can be regarded as a select transistor. By lowering the voltage applied to the select transistor, electrons are injected into the floating gate 136a close to the drain region 116 of the selected memory cell. On the other hand, when data need to be stored in a same selected memory cell, for example, the memory cell 120 in the memory unit Q2, in its floating gate 136b close to the source region 114, the control gate 138 of the selected memory cell 120 and the gate dielectric layer 144 underneath can be regarded as another select transistor. By lowering the applied voltage to this select transistor, electrons are injected into the floating gate 136b close to the source region 114 of the selected memory cell. Similarly, when data need to be stored in the selected memory cell, for example, the memory cell 118 in the memory unit Q2, in its charge-trapping layer 130, the memory cell 120 adjacent to the selected memory cell 118 and close to the drain region 116 can be regarded as a select transistor. Thus, to program the memory cells in an entire column, the aforementioned programming modes can be used to program data into the left and the right floating gates as well as the charge-trapping layer of each memory cell in sequence.

It should be noted that the programming of the left and right floating gate closest to the memory cell 120 of the drain region 116 is achieved through controlling the select unit 106. However, because no select unit or memory cell is positioned on the side close to the drain region 116, electrons will not be trapped inside the conductive spacer 108a on the sidewall of the select unit 106. Furthermore, electrons will also not be trapped inside the conductive spacer 108b on the sidewall of the memory cell 118 closest to the source region 114. The memory cell 118 can be regarded as a switching transistor for controlling the opening or closing of the channel underneath.

To erase data from the non-volatile memory as shown in FIG. 3, the selected bit line SBL and source line SSL are set in a floating state, a fourth voltage such as 9V is applied to the selected select gate line SGL of the memory column 146 and the substrate 100, and 0V is applied to the non-selected first word lines WL11˜WL1n and second word lines WL21˜WL2n so that a voltage differential is formed between the gate and the substrate. Thus, electrons are pulled from the floating gates 136a, 136b into the substrate 100 through F-N tunneling effect so that the data stored within the entire memory cell array are erased.

To perform a first reading operation as shown in FIG. 4A, 0V is applied to the selected bit line SBL, a fifth voltage such as 1.5V is applied to the second word line WL22 that couples with the selected memory cell such as the memory cell 120 of the memory unit Q2, and the source line SSL, and a sixth voltage such as 6V is applied to the other non-selected first word lines WL12˜WL1n, second word lines WL21, WL23˜WL2n and the select gate line SGL so that a first bit is read from the floating gate 136a close to the drain region 116 of the selected memory cell 120.

To perform a second reading operation as shown in FIG. 4B, 0V is applied to the selected source line SSL, a fifth voltage such as 1.5V is applied to the second word line WL22 that couples with the selected memory cell, for example, the memory cell 120 of the memory unit Q2, and the bit line SBL, and a sixth voltage such as 6V is applied to the other non-selected first word lines WL12˜WL1n, the second word lines WL21, WL23˜WL2n and the select gate line SGL so that a second bit is read from the floating gate 136b close to the source region 114 of the selected memory cell 120. According to the aforementioned reading operations, a bi-directional reading mode must be applied to read the left and right bit from the same memory cell.

To perform a third reading operation as shown in FIG. 4C, 0V is applied to the selected bit line SBL, a fifth voltage such as 1.5V is applied to the first word line WL12 that couples with a selected memory cell, for example, the memory cell 118 of the memory unit Q2, and the source line SSL, and a sixth voltage such as 6V is applied to the other non-selected first word lines WL11, WL13˜WL1n, second word lines WL21˜WL2n and the selected gate line SGL so that a third bit is read from the charge-trapping layer 130 of the selected memory cell 118.

The method of operating the non-volatile memory according to the present invention utilizes source-side injection effect for programming data into the memory and F-N tunneling effect to erase data from the memory cells. Furthermore, a bi-directional reading scheme is used to read the left and the right data bit from a selected memory cell. Because the electron injection efficiency is higher in the present invention, the memory cell current can be reduced and the operating speed can be increased. As a result, current consumption is minimized and power loss from the entire chip is reduced.

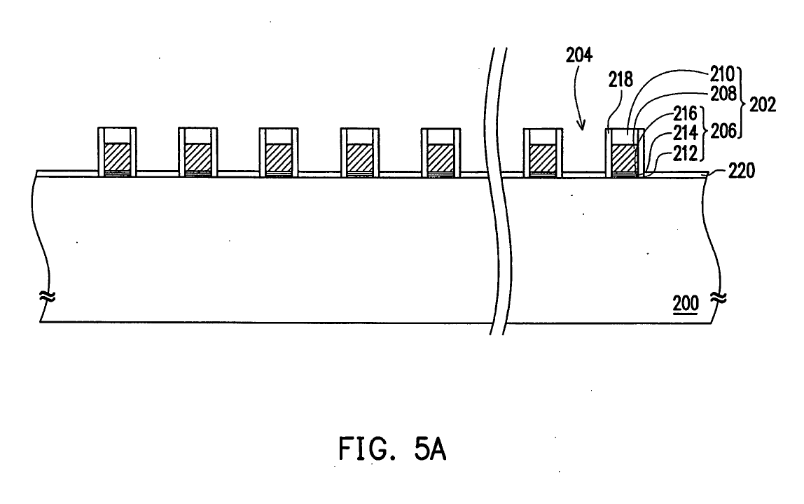

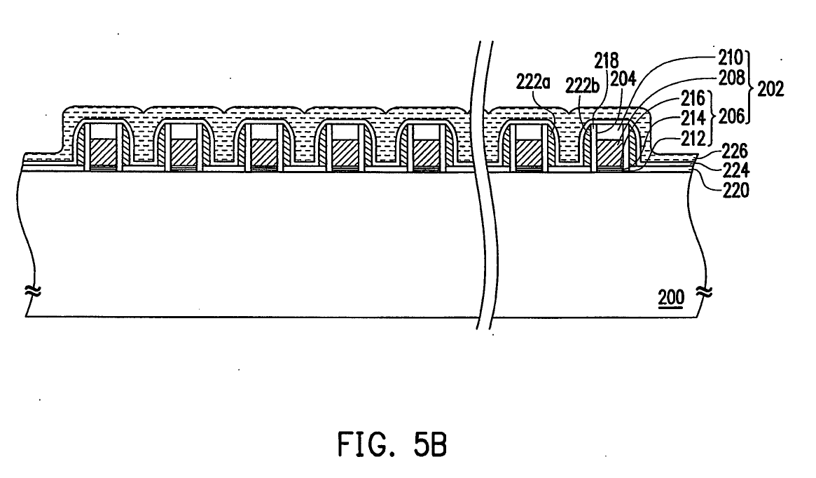

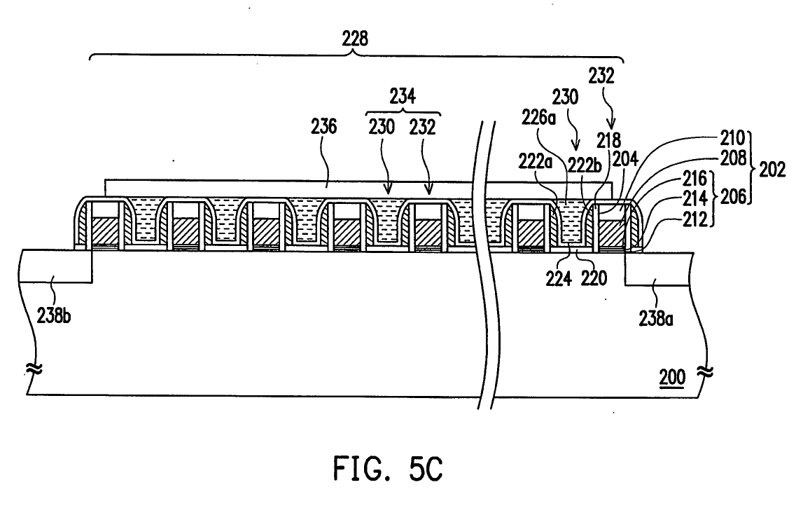

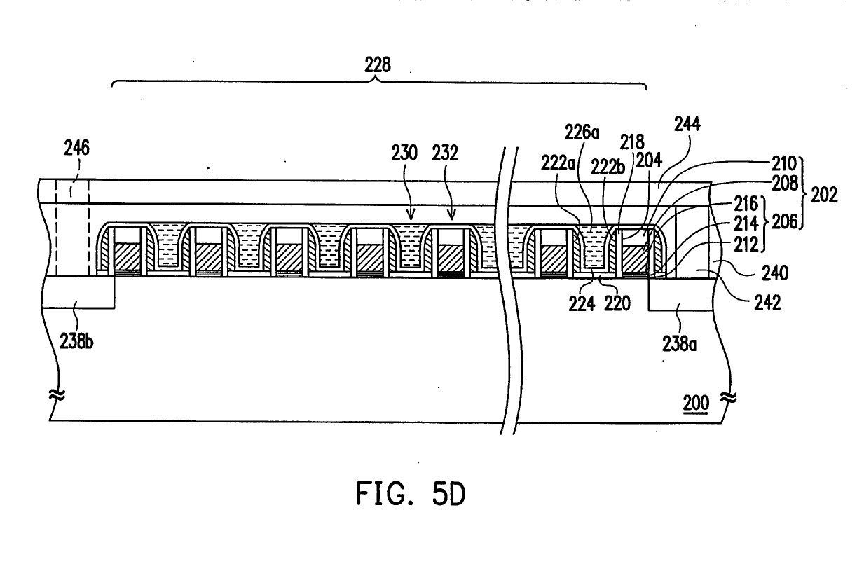

FIGS. 5A through 5D are schematic cross-sectional views showing the steps for fabricating a non-volatile memory according to the present invention. In fact, FIGS. 5A through 5D are cross-sectional views along line A-A′ of FIG. 1A. First, as shown in FIG. 5A, a substrate 200 such as a silicon substrate is provided. The substrate 200 has a device isolation structure (not shown) therein. Then, a plurality of stacked gate structures 202 is formed on the substrate 200 such that there is a gap 204 between every pair of stacked gate structures 202. Each stacked gate structure 202 includes a composite layer 206, a conductive layer 208 (a gate) and a cap layer 210, for example. The method of forming the stacked gate structures 202 includes, for example, forming a gate dielectric material layer, a conductive material layer and an insulating material layer sequentially over the substrate 200 and patterning the aforementioned material layers by performing photolithographic and etching processes thereafter.

The composite layer 206 includes a dielectric layer 212, a charge-trapping layer 214 and a dielectric layer 216, for example. The dielectric layer 212 can be a tunneling layer for electric charges and the dielectric layer 216 can be a charge-stopping layer. The dielectric layer 212 is a silicon oxide layer formed, for example, by performing a thermal oxidation process. The charge-trapping layer 214 is a silicon nitride or a doped polysilicon layer formed, for example, by performing a chemical vapor deposition process. The dielectric layer 216 is a silicon oxide layer formed, for example, by performing a chemical vapor deposition process. Obviously, the dielectric layers 212 and 216 can be fabricated using other materials with similar properties. Furthermore, the charge-trapping layer 214 is not limited to silicon nitride layer, other types of material that can trap electric charges including tantalum oxide, titanium-strontium acid and hafnium oxide can be used.

The conductive layer 208 is a doped polysilicon formed, for example, by depositing undoped polysilicon to form an undoped polysilicon layer in a chemical vapor deposition process and then performing an ion implant process thereafter.

The cap layer 210 is a silicon oxide layer formed, for example, by performing a chemical vapor deposition process using tetra-ethyl-ortho-silicate (TEOS)/ozone (O3) as the reactive gases.

Thereafter, a plurality of insulating layers 218 are formed on the sidewalls of the stacked gate structures 202 within the gaps 204 and a tunneling dielectric layer 220 is formed on the upper surface of the substrate 200. The insulating layers 218 and the tunneling dielectric layer 220 are formed, for example, by performing a conventional oxidation process. Furthermore, the insulating layers 218 and the tunneling dielectric layer 220 are formed in the same oxidation process. Through the oxide layer formed in the oxidation process, the oxide layer on the sidewalls of the stacked gate structures 202 can be used to isolate two conductive layers in a subsequent process and hence serve as an insulating layer. On the other hand, the oxide layer on the surface of the substrate 200 can serve as a tunneling dielectric layer for facilitating the tunneling of electric charges.

As shown in FIG. 5B, conductive spacers 222a and 222b are formed on the insulating layer 218 on the respective sidewalls of stacked gate structures 202. The conductive spacers 222a and 222b are fabricated using doped polysilicon, for example. The method of forming the conductive spacers 222a and 222b includes depositing conductive material to form a conductive layer that covers the stacked gate structures 202 and performing a self-aligned anisotropic etching operation to remove a portion of the conductive layer. Specifically, the conductive spacers 222a and 222b within the gap 204 serve as floating gates. Furthermore, because the conductive spacers 222a and 222b are fabricated in the same process and symmetrical to each other, the memory can operate with a higher degree of uniformity.

Thereafter, an inter-gate dielectric layer 224 is formed over the substrate 200 to cover at least the conductive spacers 222a and 222b. The inter-gate dielectric layer 224 is a silicon oxide layer or an oxide/nitride/oxide stack material, for example.

After that, a conductive layer 226 is formed over the substrate 200. The conductive layer 226 completely fills at least the gap 204 between two adjacent stacked gate structures 202. The conductive layer 226 is a doped polysilicon layer formed, for example, by depositing undoped polysilicon to form an undoped polysilicon layer in a chemical vapor deposition process and then performing an ion implant process thereafter.

As shown in FIG. 5C, a portion of the conductive layer 226 is removed until the cap layer 210 is exposed so that a plurality of gates 226a are formed in the respective gaps between two adjacent stacked gate structures 202. The gates 226a can serve as control gates. The gates 226a together with the stacked gate structures 202 form a memory cell column 228. The method of removing a portion of the conductive layer 226 includes performing a etching back operation or a chemical-mechanical polishing operation. In the memory cell column 228, the (control) gate 226a, the gate dielectric layer 220, the inter-gate dielectric layer 224, the conductive spacers 222a, 222b (the floating gates) together constitute a memory cell 230. The tunneling dielectric layer 220 and the inter-gate dielectric layer 224 underneath the gate 226a may serve as a gate dielectric layer. Furthermore, the stacked gate structure 202 can be regarded as another memory cell 232. The memory cell 230 and the memory cell 232 together form a memory unit 234 isolated from each other through the insulating layer 218. In other words, the memory cell column 228 includes a plurality of alternately laid and serially connected memory cells 230 and memory cells 232. Moreover, in the memory cell column 228, the memory cells 230 and the memory cells 232 can be regarded as a select transistor or a memory cell according to the operating mode. In addition, the outermost stacked gate structure 202 of the memory cell column 228 may be regarded as a select unit because it only serves as a select transistor in the subsequent operation. The outermost stacked gate structure 202 on the other side of the memory cell column 228 may be regarded as a switching unit because it only serves as a switching transistor in the subsequent memory operation.

Thereafter, a patterned mask layer 236 that exposes the areas for forming the desired source region and the desired drain region is formed over the substrate 200. An etching operation is carried out to remove any residual material of the conductive layer 226, the tunneling dielectric layer 220 or the inter-gate dielectric layer 224 on the areas for forming the source and the drain region.

After that, an ion implantation process is carried out using the mask layer 236 as a mask to form a source region 238a and a drain regions 238b in the substrate 200. The source region 238a and the drain region 238b are disposed in the substrate 200 on the respective sides of the memory cell column 228.

As shown in FIG. 5D, the mask layer 236 is removed and then an inner dielectric layer 240 is formed over the substrate 200. The inner dielectric layer 240 is a silicon oxide layer formed, for example, by performing a chemical vapor deposition process. After that, a source line 242 is formed in the inner dielectric layer 240 to electrically connect with the source region 238a. The source line 242 is fabricated using tungsten, for example.

Thereafter, another inner dielectric layer 244 is formed over the substrate 200. The inner dielectric layer 244 is a silicon oxide layer formed, for example, by performing a chemical vapor deposition process. A bit line 246 is formed in the inner dielectric layer 244 to electrically connect with the drain region 238b. The bit line 246 is fabricated using tungsten, for example. The subsequent steps for forming a complete non-volatile memory should be familiar to those skilled in the art, thus a detailed description is not repeated.

In the method of fabricating a non-volatile memory according to the present invention, various film layers including the floating gate and control gate are formed in the space between adjacent stacked gate structures, so photolithographic and etching processes are not required to form a memory cell between two adjacent stacked gate structures. Therefore, the production process is simplified and the production cost is reduced.

In the aforementioned embodiment, the fabrication of five memory units is used to illustrate the process. However, this should by no means limit the number of memory units that can be serially connected together. In other words, the method of fabricating a non-volatile memory according to the present invention can be applied to produce a suitable number of serially connected memory units. For example, 32 to 64 memory units can be serially connected to form a single memory unit column. In fact, the process of fabricating the non-volatile memory according to the present invention is suitable for producing an entire memory cell array.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating a non-volatile memory, comprising:
providing a substrate;
forming a plurality of stacked gate structures on the substrate, wherein each stacked gate structure comprises a composite layer, a first gate and a cap layer sequentially formed on the substrate, the composite layer having at least a charge-trapping layer and there being a gap between every two stacked gate structures;
forming an insulating layer on the sidewalls of the stacked gate structures within the gaps and forming a tunneling dielectric layer on the upper surface of the substrate;
forming a plurality of conductive spacers on the insulating layers on the sidewalls of the stacked gate structures;
forming an inter-gate dielectric layer over the substrate to cover at least the conductive spacers;
forming a first conductive layer over the substrate, wherein the first conductive layer at least completely fills the gap between two adjacent stacked gate structures;
removing a portion of the first conductive layer until the cap layer is exposed to form a plurality of second gates disposed in each of the gaps between two adjacent stacked gate structures, wherein the second gates together with the stacked gate structures form a memory cell column; and
forming a source region and a drain region in the substrate on the each side of the memory cell column.

2. The method of claim 1, wherein the step of forming conductive spacers on each insulating layer on the sidewalls of the stacked gate structures comprises:
depositing a second conductive material over the substrate to form a second conductive layer that covers the stacked gate structures; and
performing a self-aligned anisotropic etching operation to remove a portion of the second conductive layer to form the conductive spacers.

3. The method of claim 1, wherein the material constituting the first gates, the conductive spacers and the first conductive layers and the second gates comprises doped polysilicon.

4. The method of claim 1, wherein the material constituting the charge-trapping layer comprises silicon oxide or doped polysilicon.

5. The method of claim 1, wherein the material constituting the insulating layer and the tunneling dielectric layers comprises silicon oxide.

6. The method of claim 1, wherein the material constituting inter-gate dielectric layer comprises silicon oxide or silicon oxide/silicon nitride/silicon oxide.

7. The method of claim 1, wherein the step for forming the source region and the drain region in the substrate comprises performing an ion implant process.
